(19) United States
(12) Patent Application Publication
(10) Pub. No.: US 2013/0045339 A1
(43) Pub. Date: Feb. 21, 2013

(54) TECHNIQUES FOR DIAMOND NUCLEATION CONTROL FOR THIN FILM PROCESSING

(71) Applicants: Ludovic Godet, Boston, MA (US); Xianfeng Lu, Beverly, MA (US); Anthony Renau, West Newbury, MA (US)

(72) Inventors: Ludovic Godet, Boston, MA (US); Xianfeng Lu, Beverly, MA (US); Anthony Renau, West Newbury, MA (US)

(73) Assignee: VARIAN SEMICONDUCTOR EQUIPMENT ASSOCIATES, INC., Gloucester, MA (US)

(21) Appl. No.: 13/210,122

(22) Filed: Aug. 15, 2011

(51) Int. Cl. H05H 1/24; C23C 16/50; B05C 11/00

(52) U.S. Cl. 427/577; 118/697; 118/719

(57) ABSTRACT

Techniques for diamond nucleation control for thin film processing are disclosed. In one particular embodiment, the techniques may be realized as a method for generating a plasma having a plurality of ions; depositing a plurality of diamond nucleation centers on a substrate with the ions in the plasma using an extraction plate having at least one gap, wherein the plasma ions pass through the at least one gap in the extraction plate to generate a focused ion beam to deposit the plurality of diamond nucleation centers; and controlling the growth of a continuous diamond film from the diamond nucleation centers on the substrate by controlling at least one of a temperature around the substrate, a temperature of the plasma, a pressure around the substrate, and a concentration of the ions in the plasma.

### FIELD OF THE DISCLOSURE

The present disclosure relates generally to process control and, more particularly, to techniques for diamond nucleation control for thin film processing.

### BACKGROUND OF THE DISCLOSURE

The synthesis and application of diamond films has myriad applications in high technology industries. Diamond films have been deposited on various non-diamond substrates, including insulators, semiconductors and metals, ranging from single crystals to amorphous materials. The success in growing diamond thin films has stimulated interest in the unique properties of diamond for technological applications. Diamond is harder than any known solid, and exhibits the highest elastic modulus, highest atomic density, highest Debye temperature, highest acoustic velocity, and highest thermal conductivity at room temperature. In addition, diamond is chemically inert, has a very low frictional coefficient and thermal expansion coefficient, and is highly transparent from the ultraviolet to the infrared spectra. Diamond is a wide band-gap semiconductor that may be useful at high temperatures or high voltages. These properties have made the use of diamond desirable for many potential applications, such as heat spreaders, optical windows, x-ray lithography, low-friction or wear resistant surface coatings, cutting tool coatings, and active electronic device elements.

Diamond film has traditionally been grown in three steps, including diamond seed, nucleation, and formation of a continuous diamond film. Nucleation refers to the beginning process of diamond formation on a substrate. Diamond film is then grown around the diamond seeds to form a continuous thin film. Among these steps, nucleation has a significant effect on the resulting film's structure, properties and surface morphology.

Two nucleation processes have traditionally been used. One process is to pre-treat a silicon wafer in diamond powder, with the result that small diamond particles stay on the surface of the wafer and act as the nucleation centers. The other process is to use bias energy to enhance the nucleation process in the very beginning of diamond growth, but without any diamond particles on the substrate to act as diamond seeds for the nucleation process.

However, there are problems and shortcomings associated with these traditional processes. For example, it may be difficult to grow diamond films with good uniformity over a large area. These traditional processes may require high temperature and high pressure, and therefore may not be compatible with substrate materials that are susceptible to high temperature or high pressure. Also, the formed nucleation centers may not be substantially uniform in size, morphology and distribution, which may result in non-uniform diamond growth.

In view of the foregoing, it may be understood that there may be significant problems and shortcomings associated with current nucleation control technologies.

### SUMMARY OF THE DISCLOSURE

Techniques for diamond nucleation control for thin film processing are disclosed. In one particular embodiment, the techniques may be realized as a method for generating a plasma having a plurality of ions; depositing a plurality of diamond nucleation centers on a substrate with the ions in the plasma using an extraction plate having at least one gap, wherein the plasma ions pass through the at least one gap in the extraction plate to generate a focused ion beam to deposit the plurality of diamond nucleation centers; and controlling the growth of a continuous diamond film from the diamond nucleation centers on the substrate by controlling at least one of a temperature around the substrate, a temperature of the plasma, a pressure around the substrate, and a concentration of the ions in the plasma.

In accordance with other aspects of this particular embodiment, the depositing a plurality of diamond nucleation centers on a substrate includes propagating the plurality of diamond nucleation centers in a direction of motion by moving the extraction plate having at least one gap and the focused ion beam in the direction of motion.

In accordance with further aspects of this particular embodiment, the at least one gap includes at least one slot having at least one of a length, a width, and a shape arranged to control at least one of a size, a distribution, and a morphology of the diamond nucleation centers on the substrate when the focused ion beam strikes the substrate to form the plurality of diamond nucleation centers.

In accordance with additional aspects of this particular embodiment, the at least one gap includes a plurality of apertures having at least one of a size, a distribution, and a shape arranged to control at least one of a size, a distribution, and a morphology of the diamond nucleation centers on the substrate when the focused ion beam strikes the substrate to form the plurality of diamond nucleation centers.

In another particular embodiment, the techniques may be realized as a system for diamond nucleation control for thin film processing, the system comprising a plasma processing module for generating a plasma having a plurality of ions; one or more extraction plates having at least one gap for forming a deposition of a plurality of diamond nucleation centers on a substrate with the plurality of ions in the plasma using an extraction plate having at least one gap, wherein the plasma ions pass through the at least one gap in the extraction plate to generate a focused ion beam to form the plurality of diamond nucleation centers; and a temperature controller for controlling the growth of a continuous diamond film on the substrate by controlling at least one of a temperature around the substrate, a temperature of the plasma, a pressure around the substrate, and a concentration of ions in the plasma.

The present disclosure will now be described in more detail with reference to particular embodiments thereof as shown in the accompanying drawings. While the present disclosure is described below with reference to particular embodiments, it should be understood that the present disclosure is not limited thereto. Those of ordinary skill in the art having access to the teachings herein will recognize additional implementations, modifications, and embodiments, as well as other fields of use, which are within the scope of the present disclosure as described herein, and with respect to which the present disclosure may be of significant utility.

### BRIEF DESCRIPTION OF THE DRAWINGS

In order to facilitate a fuller understanding of the present disclosure, reference is now made to the accompanying drawings, in which like elements are referenced with like numerals. These drawings should not be construed as limiting the present disclosure, but are intended to be illustrative only.

FIG. 1 shows a flow diagram for a method of growing a diamond thin film in accordance with an embodiment of the present disclosure.

FIGS. 2A-2B show photographs from a scanning electron microscope of diamond nucleation on a substrate in accordance with an embodiment of the present disclosure.

FIG. 3 shows a photograph of nucleation centers formed in accordance with an embodiment of the present disclosure.

FIG. 4 shows a flow diagram of a method for focused-ion-beam-assisted diamond nucleation in accordance with an embodiment of the present disclosure.

FIG. 5A-5B show block diagrams for a system for focused-ion-beam-assisted diamond nucleation in accordance with an embodiment of the present disclosure.

FIGS. 6A-6C show top views of extraction plates used in focused-ion-beam-assisted diamond nucleation in accordance with an embodiment of the present disclosure.

FIGS. 7A-7D show top views and a perspective view of extraction plates used in focused deposition by sheath engineering, and a photograph from a scanning electron microscope of focused deposition by sheath engineering in accordance with an embodiment of the present disclosure.

### DETAILED DESCRIPTION OF EMBODIMENTS

The present disclosure relates to techniques for using focused ion beam deposition for diamond nucleation control in thin film processing. The diamond film grown according to the present techniques shows improved surface morphology. The improved surface morphology is seen in the diamond film exhibiting improved uniformity in size, morphology, and distribution. The present techniques include a method for plasma processing a large area diamond thin film using a focused ion beam through plasma sheath engineering. Advantageously, the present techniques result in well-controlled growth of diamond nucleation centers having improved uniformity in size, morphology and distribution.

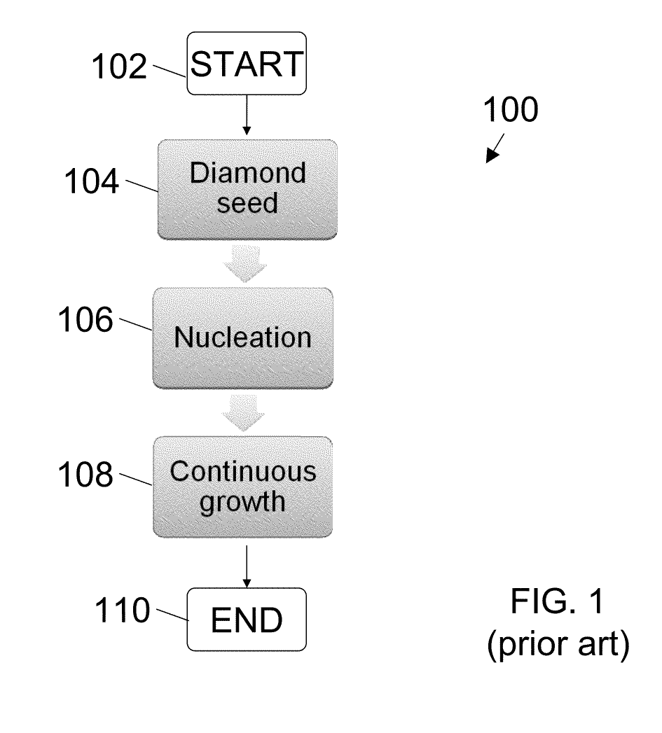

Referring now to FIG. 1, there is shown a flow diagram for a method 100 of growing diamond thin film in accordance with an embodiment of the present disclosure. FIG. 1 includes a step 104 of depositing diamond seed on a substrate, a step 106 of nucleation, and a step 108 of continuous growth of thin film. The method 100 starts at step 102 and proceeds to step 104, in which diamond seed is deposited on a substrate. The diamond seed determines the quality of the nucleation center, the growth mode, the surface morphology, the grain size, and the grain morphology. At step 106, nucleation refers to the process of forming nucleation centers from the diamond seeds. Step 106 of nucleation has a significant effect on the structure, properties, and surface morphology of the resulting continuous diamond thin film. At step 108, formation of a continuous thin film results from growth starting from the diamond seeds. The method 100 ends at step 110.

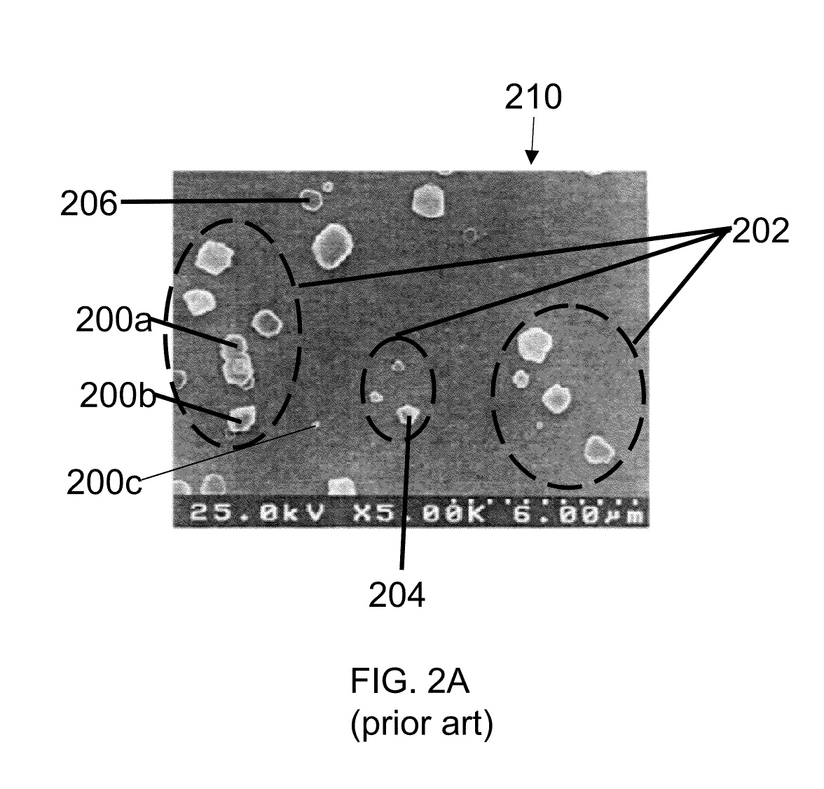

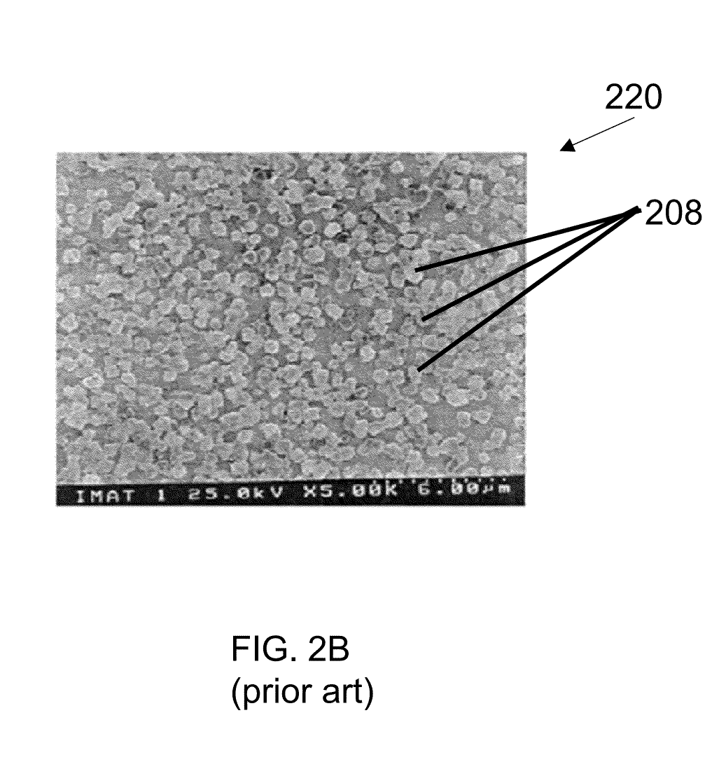

Referring to FIGS. 2A-2B, there are shown scanning electron microscope (SEM) photographs of diamond nucleation on a substrate in accordance with an embodiment of the present disclosure. FIG. 2A illustrates a SEM photograph of diamond nucleation on a small copper substrate 210 without pre-treatment. FIG. 2A includes nucleation centers 200a-c, 204, and 206, areas 202 of non-uniform nucleation centers, and a substrate 210. Nucleation centers 200a-c vary in size. Similarly, areas 202 show that distribution can vary among the nucleation centers 200a-c within each area 202, as there are large areas of substrate 210 showing through where the nucleation centers 200a-c are not uniformly distributed. Lastly, the nucleation centers 200a-c exhibit varying morphology. Morphology refers to the roughness or smoothness of the nucleation centers 200a-c. For example, nucleation center 204 exhibits a relatively rougher morphology, being shaped similar to a pentagon when viewed at high magnification. On the other hand, nucleation center 206 exhibits a relatively smoother morphology, appearing round when viewed at high magnification.

FIG. 2B illustrates a SEM photograph of diamond nucleation on a small copper substrate 220 that has been pre-treated by polishing with diamond powder. FIG. 2B includes nucleation centers 208 and a substrate 220. If the substrate 220 is of small area and is polished with diamond powder, it may be possible to grow a continuous diamond film. Nucleation centers 208 may exhibit uniform size, morphology, and distribution throughout the substrate 220. However, one shortcoming associated with nucleation control technologies has been difficulty achieving similar results in large areas. The main reason for this shortcoming is the difficulty of achieving substantially uniform diamond seed size, morphology and distribution.

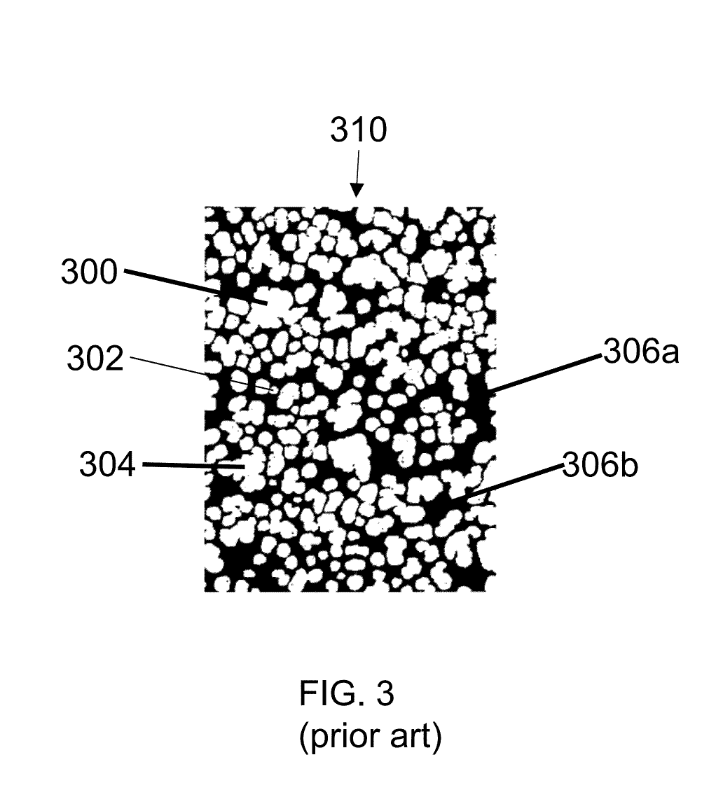

Referring to FIG. 3, there is shown a photograph of nucleation centers 300, 302, and 304 formed in accordance with an embodiment of the present disclosure. FIG. 3 includes nucleation centers 300, 302, and 304, gaps 306a, 306b in uniformity of the nucleation centers, and a substrate 310. Two diamond nucleation processes have traditionally been used to generate such nucleation centers 300, 302, and 304. One such process is to pre-treat a silicon wafer in diamond powder. The silicon wafer acts as a substrate. Small diamond particles may stay on the surface of the silicon wafer and act as the nucleation centers 300, 302, and 304. As shown in FIG. 3, the nucleation centers 300, 302, and 304 grown according to traditional methods are all of differing sizes. As described above, these traditional methods require high temperature and high pressure, and may not be compatible with substrate materials that are susceptible to high temperature or high pressure. Furthermore, the distribution of the nucleation centers may not be uniform, which may result in gaps 306a, 306b through which the substrate 310 can be seen. Referring to FIG. 1, in step 108 of the diamond growth process 100, non-uniform nucleation centers may result in non-uniform diamond growth.

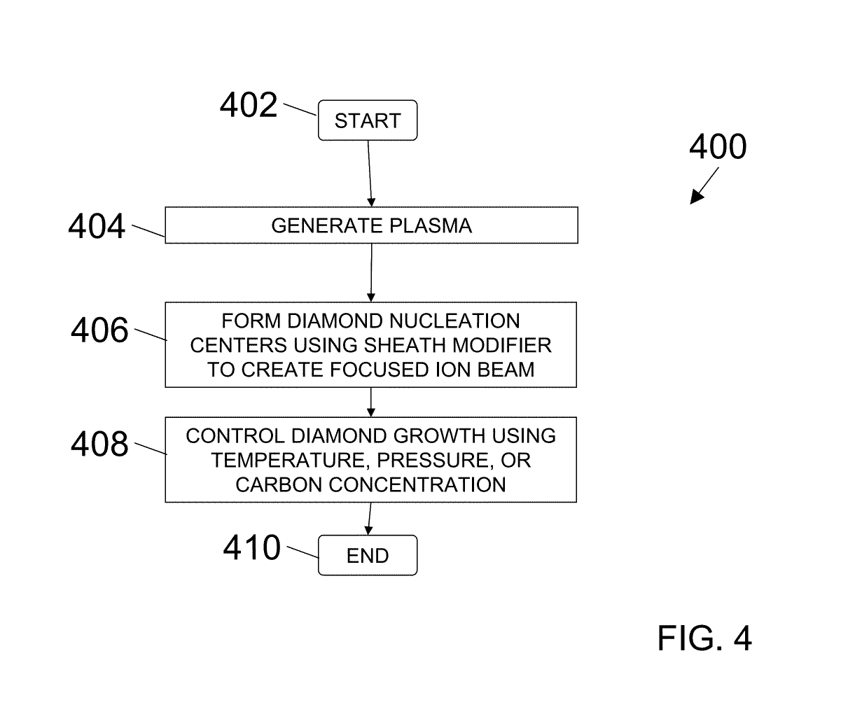

Referring to FIG. 4, there is shown a flow diagram of a method 400 for focused-ion-beam-assisted diamond nucleation in accordance with an embodiment of the present disclosure. FIG. 4 includes a step 404 of generating plasma, a step 406 of forming diamond nucleation centers using a sheath modifier, and a step 408 of controlling diamond growth using temperature or carbon concentration. The method 400 starts at step 402 and proceeds to step 404, at which plasma may be generated. At step 406, a sheath modifier may be used to focus the plasma into a focused ion beam for deposition of nucleation centers. In one embodiment, the extraction plates may be made substantially of quartz. Extraction plates may be used having apertures or slots as masks to control the size, morphology, and distribution of nucleation centers In various embodiments, sheath hardware is used having apertures of small size. At step 408, temperature control may be used to control diamond growth. In some embodiments, the presence or absence of localized heat may be used to control diamond growth. The method 400 ends at step 410. The steps 404, 406, and 408 will be described in further detail below.

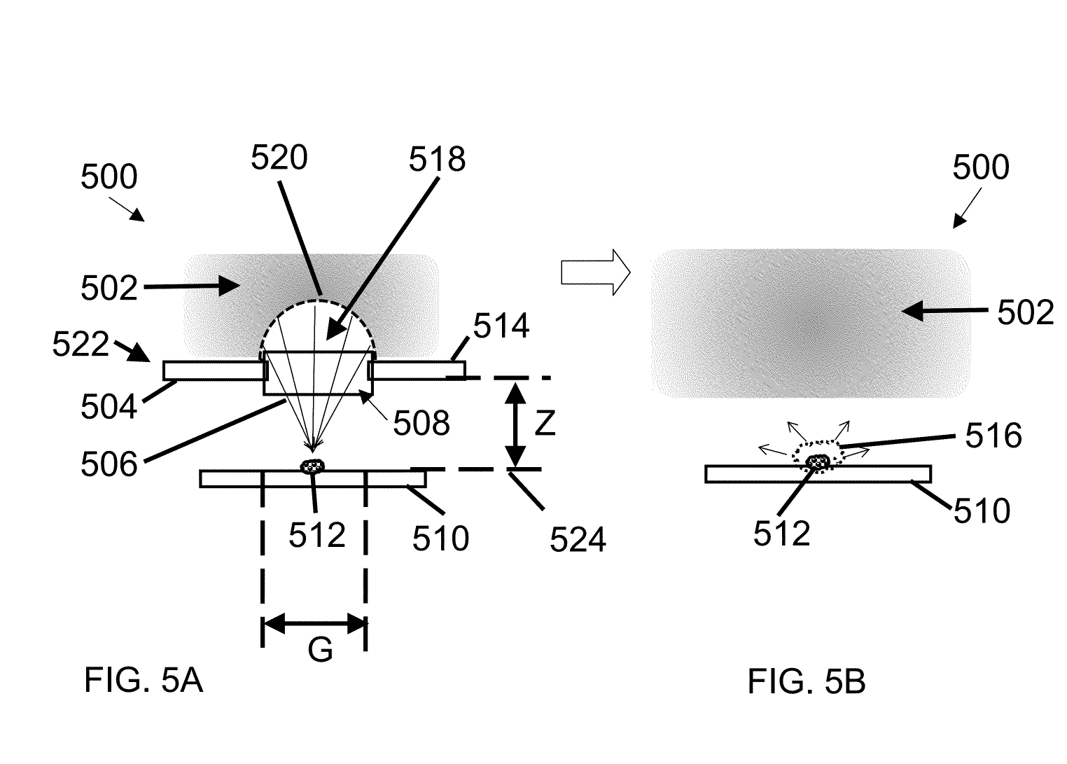

Referring to FIGS. 5A-5B, there are shown block diagrams for focused-ion-beam-assisted diamond nucleation in accordance with an embodiment of the present disclosure. FIG. 5A illustrates the nucleation phase, and FIG. 5B illustrates growing continuous thin film. As illustrated in FIG. 4, at step 406, diamond nucleation centers may be formed using a sheath modifier to modify plasma sheaths using extraction plates and strong bias energy to generate a focused ion beam. In some embodiments, the strong bias energy may be less than three kiloelectronvolts (keV). FIG. 5A illustrates step 404 showing a system 500 having a plasma sheath modifier. The system 500 employs in-situ focused surface bombardment 506 under an applied negative bias on a conductive substrate 510. FIG. 5A includes a system 500, plasma 502, an extraction plate 522 having panels 514 and 522, a plasma sheath 518 having a boundary 520, a focused ion beam 506, an aperture 508, a substrate 510 having a horizontal plane 524, and a diamond nucleation center 512. As illustrated in FIG. 4, at step 404, plasma may be generated for use in focusing an ion beam on a substrate. As illustrated in FIG. 5, plasma 502 may be generated via a plasma processing module or a number of known processes. The plasma 502 is generally a quasi-neutral collection of ions and electrons.

The ions typically have a positive charge while the electrons have a negative charge. The plasma 502 may have an electric field of, for example, approximately 0-15 V/cm in the bulk of the plasma 502. In the system 500 containing the plasma 502, ions from the plasma 502 are attracted toward a substrate 510. These ions may be attracted with sufficient energy to be implanted into the substrate 510. The plasma 502 is bounded by a region proximate the substrate 510 referred to as a plasma sheath 518. The plasma sheath 518 is a region that has fewer electrons than does the plasma 502. Hence, the differences between the negative and positive charges cause a sheath potential in the plasma sheath 502. The light emission from this plasma sheath 518 is less intense than the plasma 140 because fewer electrons are present and, hence, few excitation-relaxation collisions occur. Thus, the plasma sheath 242 is sometimes referred to as “dark space.”

The plasma sheath modifier 522 is configured to modify an electric field within the plasma sheath 518 to control a shape of a boundary 520 between the plasma 502 and the plasma sheath 518. Accordingly, ions that are attracted from the plasma 502 across the plasma sheath 518 may strike the substrate 510 at a large range of incident angles. This plasma sheath modifier 522 may be referred to as, for example, an extraction plate, focusing plate or sheath engineering plate.

As shown in FIG. 5A, the extraction plate 522 includes a pair of panels 504 and 514 defining an aperture 508 therebetween having a horizontal spacing (G). The panels 504 and 514 may be an insulator, semiconductor, or conductor. In other embodiments, the extraction plate 522 may include only one panel or more than two panels. The panels 504 and 514 may be a pair of sheets having a thin, flat shape. In other embodiments, the panels 504 and 514 may be other shapes such as tube-shaped, wedge-shaped, and/or have a beveled edge proximate the aperture. The panels 504 and 514 also may be positioned a vertical spacing (Z) above the plane 524 defined by the front surface of the substrate 510. In one embodiment, the vertical spacing (Z) may be about 1.0 to 10.0 mm.

Ions may be attracted from the plasma 502 across the plasma sheath 518 by different mechanisms. In one instance, the substrate 510 is biased using an energy differential to attract ions from the plasma 502 across the plasma sheath 518. In another instance, a plasma source that generates the plasma 502 and walls surrounding the plasma 502 are biased positively and the substrate 510 may be grounded. In one particular embodiment, the biasing may be pulsed. In yet another instance, electric or magnetic fields are used to attract ions from the plasma 502 toward the substrate 510.

Advantageously, the extraction plate 522 modifies the electric field within the plasma sheath 518 to control a shape of the boundary 520 between the plasma 502 and the plasma sheath 518. The boundary 520 between the plasma 502 and the plasma sheath 518 may have a convex shape relative to the plane 524 in one instance. When the substrate 510 is biased, for example, the ions are attracted across the plasma sheath 518 through the aperture 508 between the panels 504 and 514 at a large range of incident angles. Depending on a number of factors including, but not limited to, the horizontal spacing (G) between the panels 504 and 514, the vertical spacing (Z) of the panels 504 and 514 above the plane 524, the dielectric constant of the panels 504 and 514, or other process parameters of the plasma 502, the range of incident angles may be between +60° and −60° centered about 0°. FIG. 5A illustrates the substrate 510 at a vertical spacing (Z) such that the ions are focused on the diamond nucleation center 512.

Further, the plasma preferably has a relatively higher concentration of molecules capable of forming carbon ions, compared to the concentration used in the growth step shown in FIG. 5B. In example embodiments, the plasma 502 preferably has a high methane concentration, comprising about 10% methane (CH₄) and about 90% hydrogen (H₂). Other percentages of molecules capable of forming carbon ions may be used. Other species of molecules beyond methane may be used, such as a fluorocarbon CF₄, a hydrocarbon CₓH_{y}, or a hydrofluorocarbon CHF₃. Other gases instead of, or in addition to, hydrogen may also be used, including inert gases such as He, Ne, Ar, Kr or Xe, or combinations thereof such as H₂, He, and Ar. An applied electric field may increase an ionization degree of the neutral gas molecules, energy of the ions, and a surface ion bombardment rate.

The plasma 502 is focused into a focused ion beam 506 using an extraction plate 522. In some embodiments, the extraction plate 522 is made of quartz, a semiconductor material, or a conductor material. The extraction plate 522 has an aperture 508 through which the focused beam 506 exits, and bombards or strikes the substrate 510. During the bombardment, the ionic species alter the surface of the substrate 510 and create surface structures that act as seeds 512 for diamond growth. As illustrated in FIG. 4, at step 406, the extraction plate 522 is used to focus the deposition of the diamond growth seeds 512.

In alternative embodiments, the system 500 may use an insulating substrate 510 with pulsed bias energy and charge neutralization knobs between pulses. With an insulating substrate 510, if the bias energy is active at all times, a charge from the ions may accumulate because the substrate 510 is insulated and the charge cannot dissipate. Therefore, future ions may not be able to focus on the insulating substrate 510 to deposit the diamond nucleation centers 512. With pulsed bias energy, in some embodiments the energy may have a pulse of 200 μs whereby during 100 μs, the energy is on, or pulsed, and during 100 μs, the energy is off, or a “knob.” On an insulating substrate 510, when the pulsed bias energy is on, a charge may build up on the substrate 510. When the pulsed bias energy is off, the charge may dissipate, which may allow additional ions to focus on the substrate during the next pulse. Accordingly, diamond nucleation centers 512 may still be formed on an insulating substrate 510.

In further embodiments, the system 500 may use an insulating substrate 510 with pulsed bias energy in a multi-set-point radio frequency (MSPRF) mode. In MSPRF mode, a single pulse of the energy may be divided into four phases. The phases may include pre, on, post, and final. The length and power for each phase may be controlled separately, providing more flexibility to tune the plasma 502.

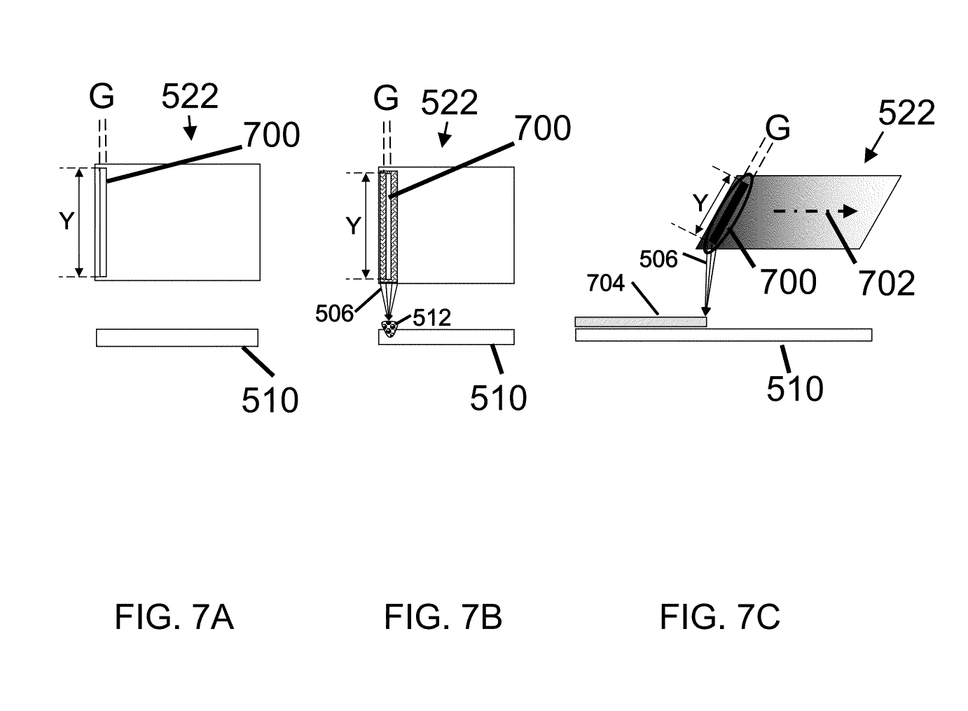

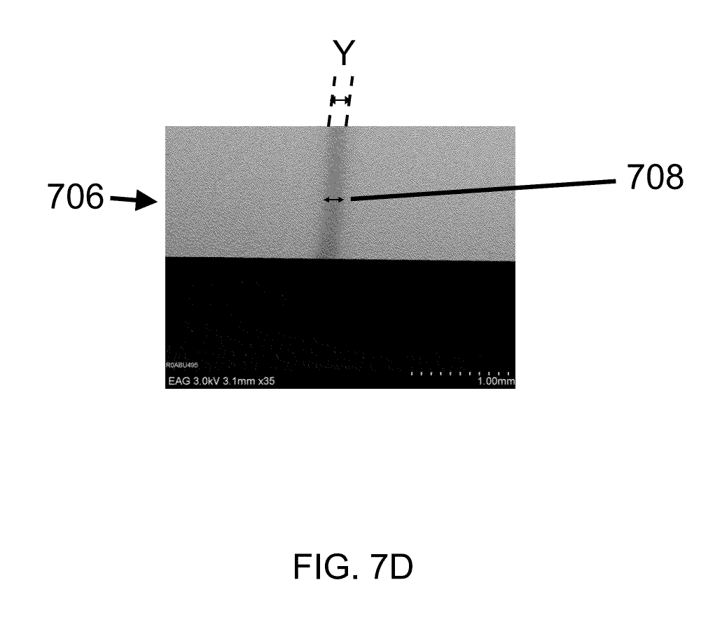

FIG. 5B illustrates a block diagram of ion-assisted diamond growth in accordance with an embodiment of the present disclosure. FIG. 5B includes the system 500 having the plasma processing module and a temperature controller, the plasma 502, the substrate 510, the diamond nucleation center 512, and ion-assisted diamond growth 516. As illustrated in FIG. 4, at step 408, temperature control may be applied to the substrate 510 to achieve continuous diamond thin film growth. This growth step is shown in further detail in FIG. 5B. After formation of the diamond seeds 512, the extraction plate 522 is removed. The methane concentration of the plasma 502 may then be reduced. The plasma 502 is preferably reduced to a low methane concentration, comprising about 1%-2% methane (CH₄) and about 98%-99% hydrogen (H₂). Ion-assisted diamond growth 516 may occur starting from the diamond seed 512 deposited in FIG. 5A. Because of the presence of methane, the plasma 502 may still have a concentration of molecules capable of forming carbon ions. Accordingly, carbon ions may be able to collect around the diamond nucleation center 512 and form the thin film. The diamond growth 516 may occur along the full substrate 510, or if a ribbon-shaped or slot aperture is used, the diamond may be grown in a ribbon, or focused line 704 (shown in FIGS. 7A-7D). As described in further detail below, the plasma processing module may control the temperature of the plasma. Because the extraction plate 522 is removed, the substrate 510 is in more direct contact with the plasma 502. Controlling the temperature of the plasma 502 controls the temperature around the substrate 510 for the diamond growth 516. In some embodiments, an angle controller may control the angle of the substrate 510 for the diamond growth 516 in a chosen direction, to control the shape of the resulting diamond thin film. The angle controller controls the angle of the substrate which changes the angle of the ions bombarding the surface from the plasma 502. The changed angle allows the system 500 to control the focal point of the focused ion beam which may alter the growth of the diamond film or the crystal orientation of the resulting diamond film.

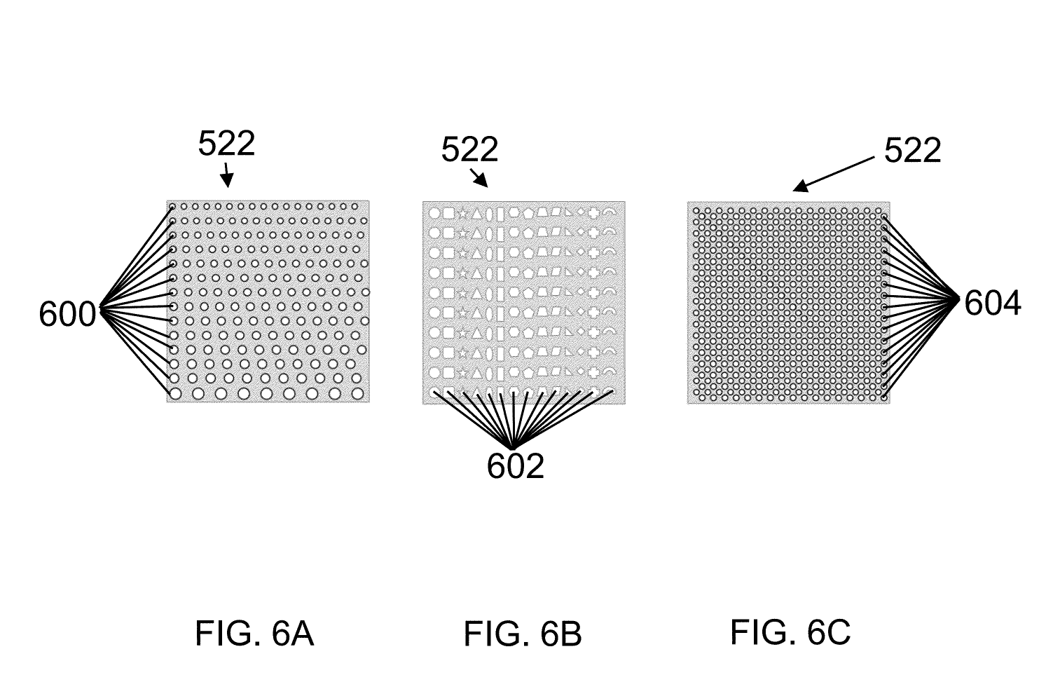

Referring to FIGS. 6A-6C, there are shown top views of extraction plates 522 having a plurality of apertures used in focused-ion-beam-assisted diamond nucleation in accordance with an embodiment of the present disclosure. FIG. 6A illustrates a top view of an extraction plate 522 to control seed size in accordance with an embodiment of the present disclosure. FIG. 6A illustrates that the size of the nucleation centers 512 (shown in FIGS. 5A-5B) can be controlled and adjusted by varying aperture size 600. FIG. 6A includes the extraction plate 522 and apertures of varying size 600. For illustrative purposes, each row of apertures shows a varying aperture size 600 increasing from top to bottom down the extraction plate 522. In other embodiments, parameters of the plasma 502 (shown in FIGS. 5A, 5B) may be controlled and adjusted to achieve the same result of controlling seed size. Example plasma parameters include power, bias energy, and pressure.

Similar to FIG. 6A, FIG. 6B illustrates a top view of an extraction plate 522 to control seed morphology in accordance with an embodiment of the present disclosure. FIG. 6B includes the extraction plate 522 and apertures of varying shape 602. The morphology of the nucleation centers 512 can be controlled and adjusted by varying the aperture shape 602. For illustrative purposes, each column of apertures shows a varying aperture shape 602. After a desired aperture size and shape are chosen, an extraction plate 522 having apertures of substantially uniform size and shape may be used to achieve improved uniformity in seed size and seed morphology.

FIG. 6C illustrates a top view of an extraction plate 522 to control the distribution of the diamond seeds 512 in accordance with an embodiment of the present disclosure. FIG. 6C includes the extraction plate 522 and apertures of substantially uniform size, shape, and distribution 604. As illustrated in FIG. 4, at step 406, the extraction plates 522 are used to control distribution of the diamond nucleation centers 512 (shown in FIGS. 5A-5B). In some embodiments, to control the distribution of diamond nucleation centers 512, the extraction plate 522 having an array of small apertures 508 (shown in FIG. 5A) may be used as a mask to define the distribution 604 of grown diamond particles. That is, the distribution of nucleation centers 512 may be easily controlled by varying aperture distribution 604 in the extraction plate 522. Through use of the extraction plate 522, the nucleation centers 512 may be formed in the regions of the substrate 510 exposed by small apertures 508 in the extraction plate 522. The focused ion beam 506 (shown in FIG. 5A) is then used to deposit diamond seeds 512 onto the substrate 510 (shown in FIGS. 5A-5B). Advantageously, the result of adjusting the aperture size, shape, and distribution in the extraction plate 522, or of controlling the plasma parameters, is that the diamond seed size, morphology, and distribution may be controlled when deposited onto the substrate 510. As described in FIG. 5A, the system 500 may also adjust the vertical distance (Z) between the extraction plate 522 and the substrate 510 to control the diamond seed size, morphology, and distribution.

Referring to FIGS. 7A-7C, there are shown top and perspective views of an extraction plate 522 having at least one rectangular slot used in focused-ion-beam-assisted diamond nucleation in accordance with an embodiment of the present disclosure. FIG. 7A includes a substrate 510 and an extraction plate 522 with a rectangular slot 700. The extraction plate 522 having a rectangular slot 700 may be used with a substrate 510. The extraction plate 522 has a vertical length (Y) and a horizontal gap (G). As illustrated in FIG. 4 in step 406, a sheath modifier may be used to grow crystal seeds using a focused ion beam. FIG. 7B includes a focused ion beam 506 created by the sheath modifier, the substrate 510, a diamond seed 512, and the extraction plate 522 with rectangular slot 700. FIG. 7B illustrates that diamond seed 512 may be created using an extraction plate 522 with rectangular slot 700. The vertical length (Y) and the horizontal gap (G) (shown in FIG. 7A) control the size, morphology, and distribution of the resulting ribbon of diamond seed 512 formed by the focused ion beam 506. FIG. 7C includes a focused ion beam 506 created by the sheath modifier, the substrate 510, a diamond seed 512, the extraction plate 522 with rectangular slot 700, a direction 702 of motion, and a diamond layer 704. FIG. 7C illustrates crystal propagation by moving the extraction plate 522 in a direction 702 of motion. This scanning of the extraction plate 522 across the substrate 510 in a direction 702 of motion may result in a diamond layer 704 being created in a focused deposition on the substrate 510. The vertical length (Y) of the extraction plate 522 controls the width of the resulting focused deposition.

FIG. 7D illustrates an image 706 from a scanning electron microscope of focused deposition by sheath engineering in accordance with an embodiment of the present disclosure. FIG. 7D includes a line structure 708 of focused width. FIG. 7D shows a line 708 having a width of about 133 micrometers (μm). The line 708 results from the scanning process illustrated in FIGS. 7A-7C across the substrate 510. To deposit the line structure 704, an extraction plate 522 with at least one rectangular slot 700 may be used (illustrated in FIGS. 7A-7C). During the deposition, the extraction plate 522 may be moved to the top of a silicon wafer. The silicon wafer may be used as the substrate 510. Only ions crossing the rectangular slot 700 of the extraction plate 522 may be deposited on the surface of the silicon wafer substrate 510. The shape, gap size (G), and vertical length (Y) of the rectangular slot 700 may determine the morphology and size of the deposition line 708. The ratio of line width to vertical length (Y) may be over 10:1, illustrating that the deposition is focused.

As illustrated in FIG. 4 at step 408, temperature control may be employed to selectively grow diamond. The diamond growth may result from the use of localized heat delivered by a focused ion beam 506 (shown in FIG. 5A). The temperature around the substrate 510 may have a significant effect on diamond growth. Using traditional methods, below a critical temperature and a critical pressure, no diamond may be grown, even with traditional methods applying bias energy. Traditional methods require critical temperatures of about 800° C.-900° C. or higher and/or critical pressures of about 30 Torr. Advantageously, the present disclosure allows diamond growth at significantly lower temperatures and significantly lower pressures. In some embodiments, the critical temperature may be about 250° C. or even lower. The critical pressure may be about 30 mTorr or even lower. To realize selective diamond growth, in the present disclosure, the plasma processing module or a temperature controller may control the temperature of the plasma 502, or around the substrate 510 (shown in FIGS. 5A-5B). Advantageously, as described above, the critical temperature for a substrate and the critical pressure around a substrate according to the present disclosure may be well below the traditional critical temperature and traditional critical pressure required for traditional diamond growth.

At this point it should be noted that diamond nucleation control in accordance with the present disclosure as described above may involve the processing of input data and the generation of output data to some extent. This input data processing and output data generation may be implemented in hardware or software. For example, specific electronic components may be employed in a focused ion beam generator or similar or related circuitry for implementing the functions associated with diamond nucleation control in accordance with the present disclosure as described above. Alternatively, one or more processors operating in accordance with instructions may implement the functions associated with diamond nucleation control in accordance with the present disclosure as described above. If such is the case, it is within the scope of the present disclosure that such instructions may be stored on one or more non-transitory processor readable storage media (e.g., a magnetic disk or other storage medium), or transmitted to one or more processors via one or more signals embodied in one or more carrier waves.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of at least one particular implementation in at least one particular environment for at least one particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1. A method for diamond nucleation control for thin film processing, the method comprising:
generating a plasma having a plurality of ions;
depositing a plurality of diamond nucleation centers on a substrate with the ions in the plasma using an extraction plate having at least one gap, wherein the plasma ions pass through the at least one gap in the extraction plate to generate a focused ion beam to deposit the plurality of diamond nucleation centers; and
controlling the growth of a continuous diamond film from the diamond nucleation centers on the substrate by controlling at least one of a temperature around the substrate, a temperature of the plasma, a pressure around the substrate, and a concentration of the ions in the plasma.

2. The method of claim 1, wherein the depositing a plurality of diamond nucleation centers on a substrate includes propagating the plurality of diamond nucleation centers in a direction of motion by moving the extraction plate having at least one gap and the focused ion beam in the direction of motion.

3. The method of claim 1, wherein the at least one gap includes at least one slot having at least one of a length, a width, and a shape arranged to control at least one of a size, a distribution, and a morphology of the diamond nucleation centers on the substrate when the focused ion beam strikes the substrate to form the plurality of diamond nucleation centers.

4. The method of claim 1, wherein the at least one gap includes a plurality of apertures having at least one of a size, a distribution, and a shape arranged to control at least one of a size, a distribution, and a morphology of the diamond nucleation centers on the substrate when the focused ion beam strikes the substrate to form the plurality of diamond nucleation centers.

5. The method of claim 4, wherein the plurality of apertures is configured according to at least one of size, shape, and distribution to result in at least one of a substantially uniform size, a substantially uniform morphology, and a substantially uniform distribution of the diamond nucleation centers.

6. The method of claim 1, wherein the controlling the growth of the continuous diamond film on the substrate includes controlling at least one of a localized temperature and a localized pressure around regions of the substrate to stay around at least one of a critical temperature and a critical pressure for diamond growth when masked by the extraction plate.

7. The method of claim 6, wherein the critical temperature is below about 250° C.

8. The method of claim 6, wherein the critical pressure is below about 30 mTorr.

9. The method of claim 1, wherein the depositing the plurality of diamond nucleation centers includes the plasma having a higher methane concentration; and wherein the controlling the growth of the continuous diamond film includes the plasma having a lower methane concentration to control the concentration of the ions in the plasma.

10. The method of claim 9, wherein the higher methane concentration is about 10%.

11. The method of claim 9, wherein the lower methane concentration is about 1%-2%.

12. At least one processor readable storage medium storing a computer program of instructions configured to be readable by at least one processor for instructing the at least one processor to execute a computer process for performing the method as recited in claim 1.

13. A system for diamond nucleation control for thin film processing, the system comprising:
a plasma processing module for generating a plasma having a plurality of ions;
one or more extraction plates having at least one gap for depositing of a plurality of diamond nucleation centers on a substrate with the plurality of ions in the plasma using an extraction plate having at least one gap, wherein the plasma ions pass through the at least one gap in the extraction plate to generate a focused ion beam to form the plurality of diamond nucleation centers; and
a temperature controller for controlling the growth of a continuous diamond film on the substrate by controlling at least one of a temperature around the substrate, a temperature of the plasma, a pressure around the substrate, and a concentration of ions in the plasma.

14. The system of claim 13, wherein the depositing a plurality of diamond nucleation centers on a substrate includes propagating the plurality of diamond nucleation centers in a direction of motion by moving the extraction plate having at least one gap and the focused ion beam in the direction of motion.

15. The system of claim 13, wherein the at least one gap includes at least one slot having at least one of a length, a width, and a shape arranged to control at least one of a size, a distribution, and a morphology of the diamond nucleation centers on the substrate when the focused ion beam strikes the substrate to form the plurality of diamond nucleation centers.

16. The system of claim 13, wherein the at least one gap includes a plurality of apertures having at least one of a size, a distribution, and a shape arranged to control at least one of a size, a distribution, and a morphology of the diamond nucleation centers on the substrate when the focused ion beam strikes the substrate to form the plurality of diamond nucleation centers.

17. The system of claim 13, wherein the controlling the growth of the continuous diamond film on the substrate includes controlling at least one of a localized temperature and a localized pressure around regions of the substrate to stay around at least one of a critical temperature and a critical pressure for diamond growth when masked by the extraction plate.

18. The system of claim 13, wherein the depositing the plurality of diamond nucleation centers includes the plasma having a higher methane concentration; and wherein the controlling the growth of the continuous diamond film includes the plasma having a lower methane concentration to control the concentration of the ions in the plasma.

19. The system of claim 18, wherein the higher methane concentration is about 10%; and wherein the lower methane concentration is about 1%-2%.

20. An article of manufacture for diamond nucleation control for thin film processing, the article of manufacture comprising:
at least one processor readable storage medium; and
instructions stored on the at least one medium;
wherein the instructions are configured to be readable from the at least one medium by at least one processor and thereby cause the at least one processor to operate so as to:
generate a plasma having a plurality of ions;
deposit a plurality of diamond nucleation centers on a substrate with the ions in the plasma using an extraction plate having at least one gap, wherein the plasma ions pass through the at least one gap in the extraction plate to generate a focused ion beam to deposit the plurality of diamond nucleation centers; and
control the growth of a continuous diamond film from the diamond nucleation centers on the substrate by controlling at least one of a temperature around the substrate, a temperature of the plasma, a pressure around the substrate, and a concentration of the ions in the plasma.
